(19) United States
(12) Patent Application Publication
(10) Pub. No.: US 2006/0231919 A1
(43) Pub. Date: Oct. 19, 2006

(54) Passive microwave device and method for producing the same

(76) Inventors: Robert J. Blacka, Pennsauken, NJ (US); Gene A. Perschnick, Palm Bay, FL (US); Robert Wright, Tequesta, FL (US)

Correspondence Address: MORGAN LEWIS & BOCKIUS LLP, 1111 PENNSYLVANIA AVENUE NW, WASHINGTON, DC, 20004, US

(21) Appl. No.: 11/107,469

(22) Filed: Apr. 15, 2005

(51) Int. Cl. H01L 29/00

(52) U.S. Cl. 257/528

(57) ABSTRACT

The present invention provides an electrical circuit component, specifically a passive microwave device, and a method for producing the same. In one embodiment, the present invention provides an electrical circuit component, comprising: at least one patterned resistive area on a first surface of a diamond substrate, a first patterned conductive area on the first surface of the diamond substrate, and a second patterned conductive area on a second surface of the diamond substrate. The patterned resistive area may comprise a very thin film of tantalum nitride or a very thin film of tantalum nitride and a thin film of nichrome. The patterned conductive area may comprise a layer of titanium-tungsten, a layer of gold, and optionally a layer of nickel. Alternatively, the patterned conductive area may comprise a layer of chrome, a layer of copper, a layer of gold, and optionally a layer of nickel.

### FIELD OF THE INVENTION

The invention relates to a passive RF/microwave device and a method for producing the same.

### BACKGROUND OF THE INVENTION

The majority of passive microwave devices produced today are constructed with aluminum oxide (Al₂O₃), beryllium oxide (BeO), or aluminum nitride (AlN) substrates. These substrate materials have been chosen because of their particular mechanical, thermal, and/or electrical properties, as well as cost and environmental considerations. For example, the selection of alumina is due to its good mechanical strength and relatively low cost. BeO is used when superior thermal properties and low dielectric constants are needed. When high thermal conductivity is required without the environmental problems associated with BeO, AlN substrates are selected.

Resistors, attenuators, and terminations are common applications of passive microwave devices. These types of devices are designed to convert excess RF energy into heat. Generally, the amount of heat a device can dissipate depends largely on the choice of substrate material and the physical size of the resistor area. Even though BeO and AlN are used to dissipate large amounts of power due to their superior thermal properties, there are practical limitations as to how much power can be dissipated over any particular frequency range. For any given substrate material, as the power requirements increase, the device needs to be physically larger. However, at high gigahertz frequencies, increasing the physical size of the device reduces its ability to fully absorb RF energy and convert it to heat.

With narrower bandwidths, there are ways of working around this limitation, even at high gigahertz frequencies. Passive tuning networks consisting of inductors, capacitors, and impedance transformers can be utilized to optimize the response and maximize the RF absorption at any particular frequency. However, tuning networks have limited usefulness over wide bandwidths. Thus, there is no practical way of producing chip resistors, attenuators and terminations on conventional substrates such as alumina, BeO, and AlN that have both high power capability and wide bandwidth at high gigahertz frequencies.

Yet, as practical uses continue to be discovered for devices operating at high gigahertz frequencies, the general lack of passive devices having the necessary frequency and power handling capabilities required by these new and novel applications has become a real impediment to the widespread use of such new technology. Therefore, there exists a need to produce passive microwave devices, such as resistors, terminations, attenuators, power dividers, couplers, temperature variable attenuators, and power sensing terminations, with the ability to satisfy these new and challenging technical requirements in a small, efficient package.

### SUMMARY OF THE INVENTION

Generally, the present invention provides an electrical circuit component, more specifically a passive RF/microwave device and a method for producing the same. In one embodiment, the present invention provides an electrical circuit component comprising: at least one patterned resistive area on a first surface of a diamond substrate, a first plurality of patterned conductive areas on the first surface of the diamond substrate, and a second plurality of patterned conductive areas on a second surface of the diamond substrate. The patterned resistive area may comprise a very thin film of tantalum nitride or a very thin film of tantalum nitride and a thin film of nichrome. The patterned conductive areas may comprise a layer of titanium-tungsten, a layer of gold, and optionally a layer of nickel. Alternatively, the patterned conductive area may comprise a layer of chrome, a layer of copper, a layer of gold, and optionally a layer of nickel.

In another embodiment, the present invention provides a method of manufacturing an electrical circuit component comprising: loading at least one diamond substrate into a thin film deposition system, wherein the diamond substrate has a first surface and a second surface; depositing at least one layer of resistive material on the first surface; depositing at least one layer of conductive material on the resistive material and on the second surface; removing the diamond substrate from the sputtering system; and creating a circuit pattern on the first surface and on the second surface. The method may also include cleaning the diamond substrate, heat-treating the diamond substrate, applying a protective coating onto the resistor pattern on the first surface and onto the second surface, and singulating the diamond substrate into individual electrical circuit components.

### BRIEF DESCRIPTION OF THE DRAWINGS

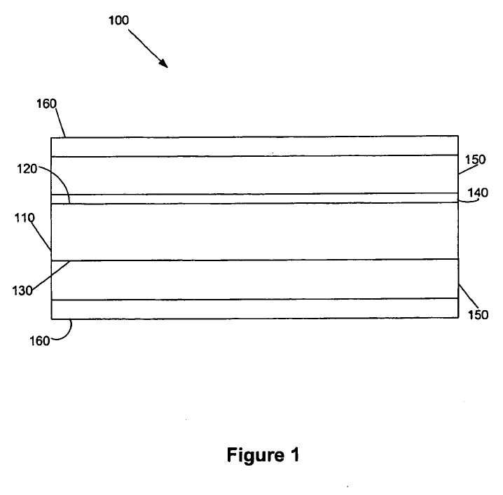

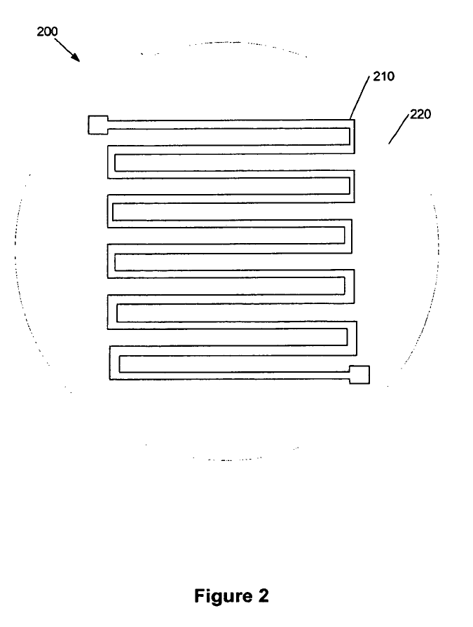

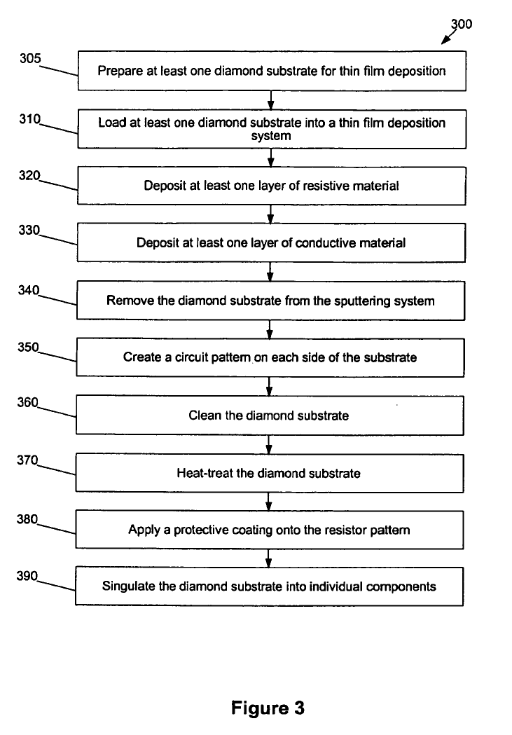

These and other objects, features and advantages of the invention will be more readily apparent from the following detailed description in which: FIG. 1 is a side view of an illustrative embodiment of the invention; FIG. 2 is a top view of an illustrative embodiment of the invention; and FIG. 3 is a flowchart for the process of manufacturing the embodiment of FIG. 1.

### DETAILED DESCRIPTION

Generally, the present invention provides a passive microwave device and a method for producing the same. By way of example, the passive microwave device can be a resistor, termination, attenuator, power divider, coupler, temperature variable attenuator (TVA), or power sensing termination (PST). The device can handle microwave frequencies of about 1 to 100 GHz and the power requirements associated with the use of such microwave frequencies, such as 1 to 500 watts. Moreover, it can be embodied in a small and efficient package. The following text in connection with the figures describes various embodiments of the present invention. The following description, however, is not intended to limit the scope of the present invention. It should be appreciated where the same numbers are used in different figures, they refer to the same structure or element.

FIG. 1 is a side view of a coated passive device 100 formed in accordance with the invention. The coated passive device 100 comprises a diamond substrate 110 with a first surface 120 and a second surface 130. On first surface 120 are a layer of resistive material 140 and a layer of conductive material 150. On second surface 130 is a layer of conductive material 150. A protective coating 160 covers the layer of conductive material 150 on both sides of the device. Depending on the device requirements, there may be additional layers of resistive material on the first surface 120 and additional layers of conductive material on the first surface 120 or second surface 130. It should also be appreciated that the substrate and layers in FIG. 1 are not drawn to scale and are shown for purposes of illustration.

For the passive microwave device of the present invention to handle microwave frequencies from 1 to 100 GHz and the power requirements associated with the use of such microwave frequencies, it is critical to use a diamond substrate. Any substrate with a diamond crystalline structure can be used, such as those produced by chemical vapor deposition (CVD), as long as it meets the device's power requirement. Diamond substrates have a thermal conductivity that is many times greater than other conventional substrate materials, which enables greater heat transfer. Greater heat transfer facilitates better device performance by quickly and effectively dissipating the heat created by the RF energy absorbed in the device, which is especially useful with smaller packages. In the present invention, the thermal conductivity of the diamond substrate should be approximately 5 to 15 Watts/cm/ degree K. In addition, the dielectric constant of the substrate should be in a range of approximately 5.2 to 6.2. The loss tangent should be less than 5.0×10⁻⁴. The volume resistivity should be greater than 10¹³ Ohm-cm. The size of an individual device is typically 0.050 inch by 0.050 inch by 0.010 inch.

The layer of resistive material 140 can be any suitable resistive material used in the art. Examples of typical resistive materials include nitrides, oxides, carbides, silicides, and borides of various metals or metalloids, such as tantalum, magnesium, niobium, zicronium, calcium, vanadium, alkaline earth metals, and silicon. In one embodiment, the resistive material should be capable of handling a power density of at least 13,800 watts per square inch and should have a sheet resistance value of approximately 10 to 200 Ohms/square. In a preferred embodiment, the layer of resistive material 140 is tantalum nitride. To accommodate the high power requirements associated with passive microwave devices, the layer of tantalum nitride should be very thin so that the device can carry greater amounts of power. A thick resistive film on the passive microwave device of the present invention would not carry as much power, making it commercially unviable. In another preferred embodiment, there are two layers of resistive material, tantalum nitride and nichrome. Specifically, a very thin layer of tantalum nitride is formed on the diamond substrate 110 and a layer of nichrome is formed on the tantalum nitride layer, in which the nichrome comprises approximately 80% nickel and 20% chromium by weight.

The layer of conductive material 150 can be any suitable conductive material used in the art, such as any one of a variety of metals or combination of metals. Common conductive metals include aluminum, tantalum, molybdenum, titanium, tungsten, gold, and copper. Furthermore, the layer of conductive material 150 can of any suitable thickness, depending on the device requirements. In a preferred embodiment, the layer of conductive material comprises at least two layers of conductive material, namely a layer of titanium-tungsten and a layer of gold. On surface 120 of substrate 110, the titanium-tungsten layer is disposed over the layer of resistive material 140, and the gold layer is disposed over the titanium-tungsten layer. On the surface 130 of substrate 110, the titanium-tungster layer is disposed on the substrate 110. Optionally, a layer of nickel may be disposed between the layer of titanium-tungsten and gold. Preferably, the titanium-tungsten layer has a thickness between approximately one to four micro-inches. The gold layer has a thickness between approximately one to four micro-inches as well. The nickel layer has a thickness between approximately ten to forty micro-inches.

In addition, each conductive layer also serves other functions for the microwave passive device. For example, the titanium-tungsten layer serves as an adhesion layer for the gold layer. Gold is useful in facilitating electrical connectivity between the passive microwave device and another component, as well as protecting from oxidation other materials beneath it such as nickel. Nickel is used when soldering a component onto the microwave passive device because soldering directly onto the gold layer may destroy the gold layer. When the device does not have a nickel layer, a component may be attached to the gold layer of the microwave passive device via wire bonding and the use of an epoxy.

In another preferred embodiment, the layer of conductive material also comprises at least three layers of conductive material, which are a layer of chrome, a layer of copper, and a layer of gold. The chrome layer is disposed over the layer of resistive material 140. The copper layer is disposed over the chrome layer. The gold layer is disposed over the copper layer. Optionally, a layer of nickel may be disposed between the copper and gold layers. The thicknesses of these layers are similar to the ones used in the first embodiment. The chrome layer has a thickness of approximately 1 to 4 micro-inches. The copper layer and the nickel layer each has a thickness of approximately 10 to 40 micro-inches. The gold layer has a thickness of approximately 1 to 4 micro-inches.

As noted earlier, the conductive material 150 is present on the first surface 120 and second surface 130 of the diamond substrate 110. Layers 140 and 150 of resistive and conductive material enable formation of a termination connection on the first surface 120. Because considerable heat is generated by such a small microwave passive device, it is also desirable to attach the microwave passive device to a heat sink to enable further heat dissipation. The conductive material of the second surface 130 facilitates attachment to a heat sink. Furthermore, even though the embodiment of FIG. 1 depicts the layer of resistive material on only one surface of the substrate, the present invention is not limited to having a resistive material layer on only one surface of the substrate. For example, the second surface may have both conductive and resistive material layers to facilitate attachment to a heat sink or any other type of connection.

As described below in conjunction with FIG. 3, during manufacture of device 100, a layer of patterned photoresist (not shown) is formed on the conductive material layer 150 of the first and second surfaces 120, 130 of the diamond substrate 110. The photoresist layer may comprise any photoresist material used in the art. Photoresist materials are typically polymer-based and may have inorganic and organometallic components. The photoresist material may be a positive resist or a negative resist. The type of photoresist material to use depends on the device requirements and the desired circuit pattern. Examples of positive resists include polymethylmethacrylate (PMMA), poly-[butene-1-sulfone] (PBS) and two-component DQN resists comprising a photoactive diazoquinone ester (DQ) and a phenolic novolak resin (N). Examples of negative resists include a two component resist comprising bis(aryl)azide-sensitized rubber and cyclized poly(cis-isoprene), a copolymer of α-cyano ethylacrylate-α-amido ethylacrylate, germanium selenide, and various polyimides. The layer is patterned in known fashion such as by exposing the photoresist to actinic radiation directed through a patterned mask. Using known photolithographic techniques, the pattern is then transferred to the underlying conductive and resistive layers 150, 140.

FIG. 2 is a top view of a patterned substrate 200. A representative resistor pattern 210 covers a first surface 220 of the patterned substrate 200. The substrate 200 has a second surface (not shown) that also has a resistor pattern (not shown). It should be appreciated that the resistor pattern 210 in this Figure is not drawn to scale and is shown for purposes of illustration. The resistor pattern 210 also is not limited to the particular pattern shown. Any pattern in the art can be used, such as stripline or coplanar waveguide configuration. As indicated in the embodiment of FIG. 1, a conductive pattern may also be located on top of the resistive pattern.

FIG. 3 is a flowchart for a process 300 of manufacturing a microwave passive device. The microwave passive device is made by depositing thin films of materials onto the surfaces of a diamond substrate, wherein the diamond substrate will be subsequently referred to as “substrate” as a matter of convenience. The size of the substrate illustratively is about one inch by one inch by 0.010 inch although the invention may be practiced with other size substrates as well. Illustratively, the top and bottom surfaces are lapped to a surface finish of Ra 500 nanometers. To maximize the number of individual devices formed on the substrate, the devices are aligned in a rectangular array on the substrate.

First, in step 305, a substrate is prepared for thin film deposition by cleaning the surfaces of the substrate and loading the cleaned substrate into a carrier, where the carrier holds the substrate in place for thin film deposition and facilitates substrate movement within the thin film deposition system. The substrate is cleaned using de-ionized water, acids, alcohol or other cleaning detergents. Optionally, the substrate may be plasma cleaned. After cleaning, the substrate should be dried, using any suitable dryer known in the art, such as a spin-rinse dryer or an alcohol dryer. The transfer of the substrate to the carrier should be performed in a manner that minimizes substrate contamination. The carrier used to hold and transport the substrate should also be clean so that substrate contamination is minimized. Maintaining a clean substrate surface results in better thin film adhesion and reduces the number of defects in the finished device.

In step 310, at least one substrate is placed into a thin film deposition system by loading the carrier containing the substrate into a vacuum chamber of the system. The number of substrates placed into the thin film deposition system depends on the equipment and carrier design. Once the substrate is loaded into the vacuum chamber of the thin film deposition system, the vacuum chamber is pumped down to a base pressure that is lower than 10⁻⁶ torr and preferably lower than 10⁻⁸ torr.

The thin film deposition system used in the present invention may be any deposition system that deposits thin films through methods known in the art such as sputtering, chemical vapor deposition, ion beam deposition, plasma vapor deposition, electron beam evaporation systems, and pulsed laser deposition. Preferably, the thin films are deposited using a sputtering process, which first includes moving the substrate in front of a sputtering target, filling a vacuum chamber with an inert gas such as argon to a processing pressure range of about 2 millitorr to 30 millitorr, and striking a plasma by applying a voltage to the sputtering target causing the target material to be sputtered onto the substrate surface. Although argon is a preferred gas used for sputtering, other inert gases, such as helium, krypton or xenon from the noble gas family, can be used for sputtering. Additionally, non-inert gases such as nitrogen can also be used for sputtering depending on the desired film properties.

In step 320 at least one layer of resistive material is deposited as a thin film upon a first surface of the substrate. Generally, the chambers of a sputtering system are set up so that each chamber deposits one type of material. Therefore, where multiple layers of resistive materials are to be deposited, the substrate may be loaded or passed through a plurality of chambers to achieve such multi-layered depositions. To deposit a specific resistive material, the sputtering chamber is set up with an appropriate target containing the desired material. For example, a tantalum nitride target would be used to deposit tantalum nitride onto the substrate. In an alternative embodiment discussed below, a second surface of the substrate is also deposited with at least one layer of a resistive material.

In step 330, at least one layer of conductive material is deposited as a thin film upon the resistive material layer from step 320 and the second surface of the substrate. The sputtering of the conductive material is set up similar to the sputtering of the resistive material, except that different targets and possibly different gases are used. For example, a gold target would be used when sputtering the gold layer.

Since this device requires at least the conductive materials be deposited on both surfaces of the substrate, the conductive material may be deposited one surface at a time or two surfaces at a time. Various techniques can be used to deposit thin films on both surfaces of the substrate including first depositing one or more layers on the first surface of the substrate, removing the substrate from the sputtering system, flipping the substrate over, and reloading the substrate back into the vacuum chamber of the sputtering system for deposition onto the second surface of the substrate. This is a common procedure for sputtering onto both surfaces of a substrate because most conventional sputtering systems used in the semiconductor industry do not include dual-sided deposition capabilities. Therefore, depending on the sputtering system used, steps 320 and 330 may include a series of further intermediate steps comprising removing the substrate from the system, flipping the substrate and reloading the substrate into the system for deposition onto the second surface of the substrate.

In another embodiment, both surfaces of the substrate may be sputtered without removing the substrate from the sputtering system, flipping it, and reloading it. The substrate can be supported on an edge by a clamp and sputtering a film onto the first surface of the substrate, flipping the substrate inside the sputtering system and sputtering a second film onto the second surface of the substrate. If the sputtering system is equipped with dual sputtering targets oppositely positioned to each other such that the substrate can be positioned between the two sputtering targets, then both sides of the substrate can be coated with films simultaneously by positioning the substrate between the two targets and supplying voltages to both targets to strike plasmas between each target and the substrate.

In addition to film deposition considerations related to the sputtering system's design, other process conditions can be implemented to vary the film characteristics and properties during deposition steps 320 and 330. For example, the application of RF alternating current, direct current, and magnetic fields to the sputtering target may alter and produce other desired film properties. In another example, prior to film deposition, an application of a biased voltage to the substrate may also affect the structural or electrical properties of the deposited film.

After all the resistive and conductive materials have been deposited upon the substrate, the substrate is removed from the sputtering system at step 340. Care should be exercised when removing the substrate that the substrate does not become physically damaged or unduly contaminated.

In step 350 a circuit pattern is created in the resistive and conductive layers on both surfaces of the substrate. Generally, the creation of a circuit pattern involves several processes: applying the photoresist onto the substrate, exposing the photoresist through a pattern mask, developing the photoresist by selectively removing portions of the photoresist, etching the conductive and resistive materials from which the photoresist has been removed, and stripping the remaining photoresist. Such processes can be implemented by any method known in the art and are described in various literature, such as Semiconductor Lithography by Wayne M. Moreau (Plenum Press, New York, 1988), which is incorporated by reference herein in its entirety.

In step 360, the substrate is cleaned. At this point, the conductor and resistor patterns have been created, but there may be residual chemicals from the previous processes left on the substrate's surfaces. Therefore, cleaning at this stage removes such matter left on the substrate's surfaces. The degree of cleaning and the method of cleaning depend on the cleanliness of the substrate going into this step, which may be affected by the specific process chemicals, equipment, and environment used in the manufacture of the device up to this point. Any cleaning method known in the art may be used. For example, the substrates may be washed with a surfactant and rinsed with deionized water. Regardless how the cleaning may have been done, upon completion of step 360, the substrate should also be dried.

It should be appreciated that steps 320 to 360 may be repeated in part or in their entirety to achieve the desired circuit pattern. For example, for a complex circuit pattern, steps 320 to 360 may be repeated several times to create multi-layered and multi-patterned circuitry. In another example, deposition of materials in step 320 and 330 may be separated by other steps such that the resistive material layer is deposited first and then followed by steps 340 to 360 to create a specific resistor pattern before returning to the sputtering system for step 330 and steps 340 to 360 to create a specific conductor pattern.

Subsequently, in step 370 the substrate is heat-treated. Heat treatment of the substrate raises the resistor area to a desired final resistivity value. Generally, a heating temperature range of 200 to 400° C. is sufficient to produce the final resistivity value. The specific temperature to heat the substrate varies, depending on the resistor material and the device requirements.

Then in step 380 a protective coating is applied to the substrate. Any suitable material known in the art can be used in this step. Silicon-based materials are commonly used as the protective coating, such as silicon nitride. The protective coating protects the delicate circuits formed during step 350 from corrosion, moisture, and atmospheric contamination.

Finally, in step 390 the substrate is singulated to create individual microwave passive devices. Any method known in the art can be used to achieve singulation. Generally, the substrate is scribed first, defining the boundaries of the individual devices as well as creating the lines to initiate the severance of the substrate to form the individual devices. Preferably, a laser is used to scribe the substrate at 50 to 60% of its depth. After scribing, the substrate is separated into individual devices. Any method known in the art may be used to separate the substrate into smaller components, such as sawing or snapping.

While the foregoing discussion describes various embodiments of the present invention, it will be appreciated that the foregoing description should not be deemed limiting since additions, variations, modifications and substitutions may be made without departing from the spirit and scope of the present invention. It will be clear to one of skill in the art that the present invention may be embodied in other forms, structures, arrangements, and proportions and may use other elements, materials and components. For example, although the microwave passive device is described with conductive material layers and resistive layers, the device can be adapted with the addition of other types of material layers, such as an insulating material, to better perform other functionalities. The present disclosed embodiments are, therefore, to be considered in all respects as illustrative and not restrictive, the scope of the invention being indicated by the appended claims and not limited to the foregoing description.

What is claimed is:

1. An electrical circuit component, comprising:
at least one patterned resistive area on a first surface of a diamond substrate;
a first patterned conductive area on said first surface of said diamond substrate; and
a second patterned conductive area on a second surface of said diamond substrate,
wherein the electrical circuit component is designed to convert electrical energy in the frequency range of 1 GHz to 100 GHz to thermal energy and dissipate said energy to an attached heat sink device.

2. The component of claim 1 comprises a passive microwave device.

3. The component of claim 1, wherein said patterned resistive area comprises a thin film of tantalum nitride.

4. The component of claim 3, wherein said patterned resistive area further comprises a thin film of nichrome.

5. The component of claim 1, wherein said first patterned conductive area comprises a layer of titanium-tungsten and a layer of gold.

6. The component of claim 5, wherein said layer of titanium-tungsten has a thickness of about 1 to 4 micro-inches.

7. The component of claim 6, wherein said layer of gold has a thickness of about 1 to 4 micro-inches.

8. The component of claim 5, wherein the first patterned conductive area further comprises a layer of nickel.

9. The component of claim 8, wherein said layer of nickel has a thickness of about 10 to 40 micro-inches.

10. The component of claim 1, wherein said first patterned conductive area comprises a layer of chrome, a layer of copper, and a layer of gold.

11. The component of claim 10, wherein said layer of chrome has a thickness of about 1 to 4 micro-inches, said layer of copper has a thickness of about 10 to 40 micro-inches, and said layer of gold has a thickness of about 1 to 4 micro-inches.

12. The component of claim 11, wherein said first patterned conductive area further comprises a layers of nickel.

13. The component of claim 12, wherein said layer of nickel has a thickness of about 10 to 40 micro-inches.

14. The component of claim 1, wherein said first and second patterned conductive areas are made of the same layers of conductors.

15. The component of claim 1, wherein said patterned resistive area is disposed between said diamond substrate and said first patterned conductive area.

16. The component of claim 15, wherein said patterned resistive area comprises a stripline configuration.

17. The component of claim 16, wherein said patterned resistive area comprises a coplanar waveguide configuration.

18. The component of claim 1 further comprising at least one patterned resistive area on said second surface.

19. A method of manufacturing an electrical circuit component comprising:
loading at least one diamond substrate into a thin film deposition system, wherein said diamond substrate has a first surface and a second surface;
depositing at least one layer of resistive material on said first surface;
depositing at least one layer of conductive material on said first surface and on said second surface;
removing said diamond substrate from said sputtering system; and
creating a circuit pattern on said first surface and on said second surface,
wherein the circuit pattern defines a device designed to convert electrical energy in the frequency range of 1 GHz to 100 GHz to thermal energy and dissipate said energy to an attached heat sink device.

20. The method of claim 19, wherein said thin film deposition system comprises a sputtering system.

21. The method of claim 19, wherein said layer of resistive material comprises a thin film of tantalum nitride.

22. The method of claim 19, wherein said layer of conductive material comprises a layer of titanium-tungsten and a layer of gold.

23. The method of claim 22, wherein said layer of conductive material further comprises a layer of nickel.

24. The method of claim 19, wherein said layer of conductive material comprises layers of chrome, copper, and gold.

25. The method of claim 24, wherein said layer of conductive material further comprises a layer of nickel.

26. The method of claim 19, wherein creating said circuit pattern comprises creating a conductor pattern on said first surface and said second surface.

27. The method of claim 19, wherein creating said circuit pattern comprises creating a resistor pattern on said first surface.

28. The method of claim 27, wherein creating said resistor pattern comprises forming a stripline configuration on said diamond substrate.

29. The method of claim 19, wherein creating said resistor pattern comprises forming a coplanar waveguide configuration on said diamond substrate.

30. The method of claim 19 further comprising:
cleaning said diamond substrate;
heat-treating said diamond substrate; and
singulating said diamond substrate into individual electrical circuit components.

31. The method of claim 30, wherein said individual electrical circuit components comprise passive microwave devices.

32. The method of claim 19 further comprising depositing at least one layer of resistive material on said second surface.
